(19) United States
(12) Patent Application Publication
(10) Pub. No.: US 2007/0010100 A1
(43) Pub. Date: Jan. 11, 2007

(54) Method of plasma etching transition metals and their compounds

(75) Inventors: Usha Raghuram, San Jose, CA (US); Michael W. Konevecki, San Jose, CA (US)

Correspondence Address: MATRIX SEMICONDUCTOR, INC., 3230 SCOTT BOULEVARD, SANTA CLARA, CA, 95054, US

(73) Assignee: Matrix Semiconductor, Inc., Santa Clara, CA (US)

(21) Appl. No.: 11/179,423

(22) Filed: Jul. 11, 2005

(51) Int. Cl. H01L 21/302

(52) U.S. Cl. 438/710; 257/E21.218

(57) ABSTRACT

A method of plasma etching comprises using a primary etchant of carbon monoxide gas to etch a transition metal or transition metal compound and to form a volatile by-product of metal carbonyl.

### BACKGROUND OF THE INVENTION

### 1. Background of Prior Art

Typically transition metals and transition metal compounds are difficult to etch since most common etchants produce non-volatile byproducts which remain on the etched surface, creating defects. Therefore it would be highly desirable to have a new and improved method of plasma etching transition metal and transition metal compounds while simultaneously reducing defect levels significantly.

### BRIEF SUMMARY OF THE INVENTION

A method of plasma etching comprises using a primary etchant of carbon monoxide gas to etch a transition metal or a transition metal compound and form a volatile metal carbonyl by-product that can be efficiently removed during the plasma etch.

### BRIEF DESCRIPTION OF THE DRAWINGS

The above mentioned features and steps of the invention and the manner of attaining them will become apparent, and the invention itself will be best understood by reference to the following description of the preferred embodiment(s) of the invention in conjunction with the accompanying drawings wherein:

FIG. 1 is a scanning electron microscope (SEM) photograph of a top down view of a sputter etched nickel oxide structure showing excessive residue;

FIG. 2 is an SEM photograph of an undesirable etch profile associated with etching a sandwiched transition metal oxide stack using a sputter etch process;

FIG. 3 is diagrammatic illustration of a portion of an integrated circuit with a sandwiched transition metal oxide stack similar to that shown in the photograph of FIG. 2; and

FIG. 4 is a flowchart of a processing method which is in accordance with a preferred embodiment of the present invention.

### DETAILED DESCRIPTION OF THE PREFERRED EMBODIMENTS OF THE INVENTION

A method of plasma etching transition metals and transition metal compounds, including transition metal oxides, with carbon monoxide is disclosed. The following description is presented to enable any person skilled in the art to make and use the invention. For purposes of explanation, specific nomenclature is set forth to provide a thorough understanding of the present invention. Descriptions of specific applications and methods are provided only as examples. Various modifications to the preferred embodiments will be readily apparent to those skilled in the art, and the general principles defined herein may be applied to other embodiments and applications without departing from the spirit and scope of the invention. Thus, the present invention is not intended to be limited to the embodiments shown, but is to be accorded the widest scope consistent with the principles and steps disclosed herein.

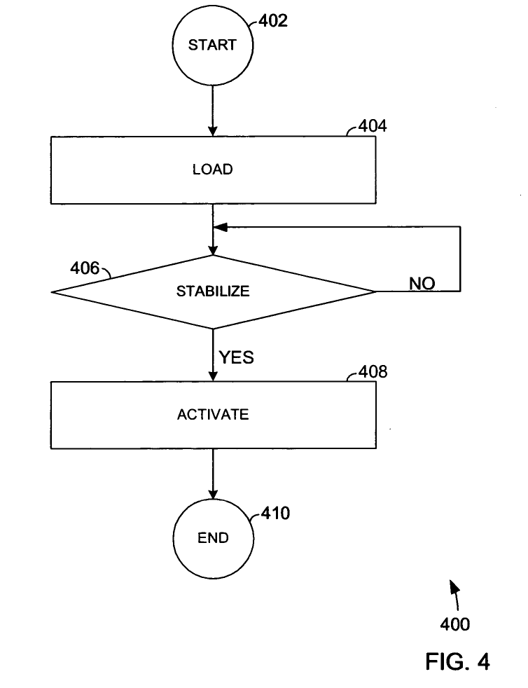

Referring now to the drawings and more particularly to FIG. 4 thereof, there is shown a flow chart of a plasma etching process 400 for etching a transition metal or transition metal compound, which method 400 is in accordance with a preferred embodiment of the present invention. The disclosed plasma etching method 400, as will be explained hereinafter in greater detail, results in a reaction between a primary etchant of carbon monoxide or carbon monoxide-based plasma and a transition metal or transition metal compound, which in turn, forms a volatile by-product of metal carbonyl, thereby promoting the quick and easy removal of metal carbonyl by-product by pumping it away from the plasma etcher as it is generated.

Before discussing the etching method 400 in greater detail, it may be beneficial to briefly review the current state of the art for etching transition metals and transition metal oxides, such as nickel oxide. To begin, it should be noted that there is very little information on plasma etching nickel oxide in the available literature. There are some references to wet etching and sputter etching in a plasma tool; however, none of the prior art specifically addresses plasma etching nickel oxide or other transition metals or transition metal compounds.

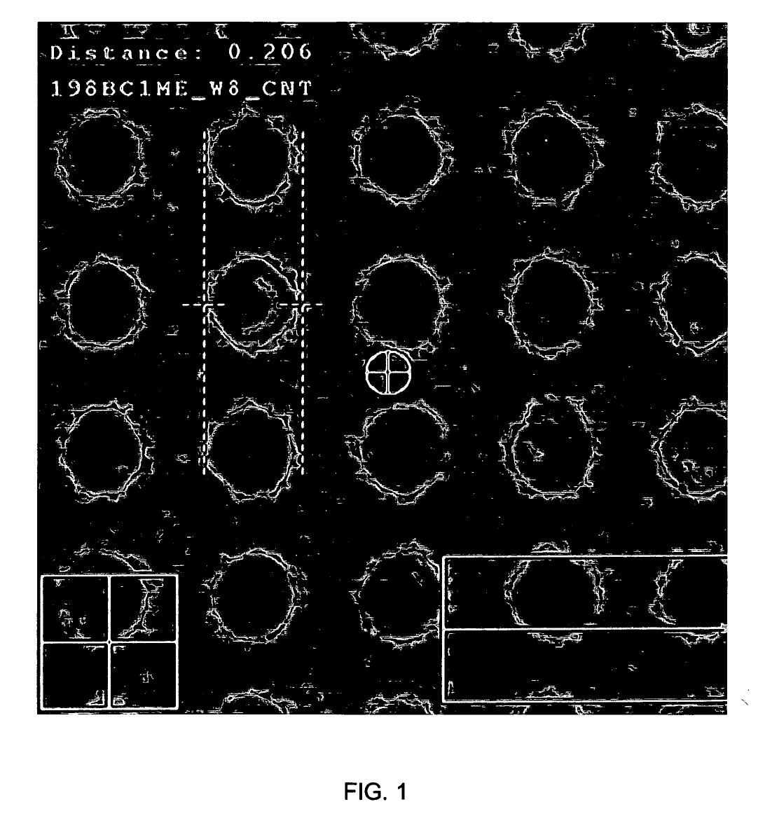

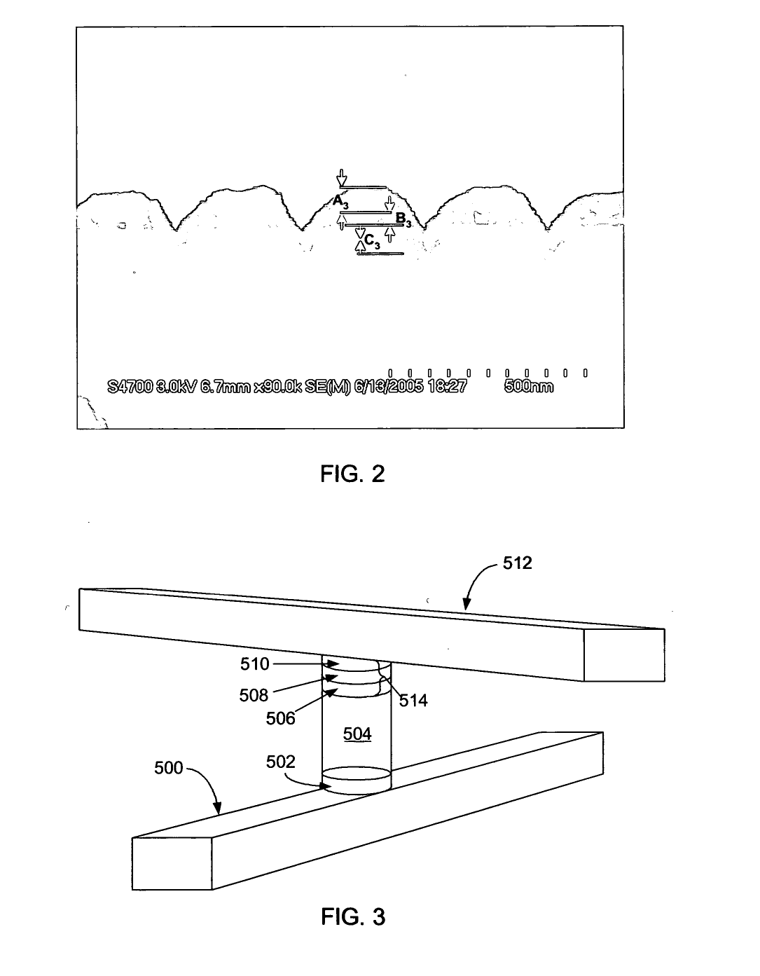

Notwithstanding the lack of literature, it is well known that nickel oxide as well as other transition metals and transition metal compounds are difficult to etch since most of the common etchants produce non-volatile by-products, such as nickel fluoride and nickel chloride in the case of nickel or nickel oxide in a fluorine or chlorine based plasma respectively. For example, with reference to etching nickel oxide, the prior art has required a high sputter component to etch, which leaves unwanted and undesired by-products as well as residues. Illustrative examples of excessive residue and poor etch profiles are depicted in the SEM photographs of FIGS. 1-2.

More particularly, etching of nickel oxide using a conventional sputtering technique is shown in the SEM photograph of FIG. 1. In this regard, it can be seen that there is a considerable amount of unwanted and undesired residue formation which is disadvantageous when devices are produced in high volume. FIG. 2 is an SEM photograph showing a cross-section of an etched stack including a layer of nickel oxide between titanium nitride layers, showing a poor etch profile. These examples demonstrate that residues cannot be effectively removed and the resulting etch profile is sloped when the etch chemistry for the material being patterned produces nonvolatile by-products. In short then, such residues and sloped pattern profiles will lead to low and unpredictable yields particularly with circuitry incorporating these structures.

Other processes, such as screen printing and photo emulsion, have been utilized in the prior art to pattern similar transition metals and their various compounds. However, these processes do not scale well to the very small dimensions of modern integrated circuits or mix conveniently with existing, readily available semiconductor processes.

Considering now the plasma etching process 400 in greater detail with reference to FIG. 4, the process begins in a plasma etcher (not shown) at a start step 402. In this regard, a chamber within the plasma etcher is loaded at a loading step 404 with one or more wafers or some other appropriate substrate having at least a layer thereon of a transition metal or a transition metal compound to be patterned.

A layer of a transition metal or transition metal compound deposited over the wafer or other suitable substrate can be patterned and etched using methods of the present invention. Any suitable transition metal can be used, including nickel, iron, cobalt, tungsten, molybdenum, manganese, and ruthenium. Similarly, transition metal compounds can be patterned and etched, including oxides, nitrides, and suicides of suitable transition metals.

After the plasma chamber is loaded with the wafers at step 404, the process advances to a stabilizing step 406, where the chamber is sealed and set to a relative low pressure to facilitate plasma etching. During the stabilizing step, which extends over a predetermined period of time, the gas sources connected to the chamber are allowed to flow into the chamber and to be pumped out and to stabilize at a given pressure set point. As will be explained hereinafter in greater detail, the gas sources allowed to flow into the chamber are a matter of choice depending upon the primary etchant desired and any additives that may be required.

After the chamber has stabilized, with the chamber pumps running, and the primary etchant gas and any desired additives flowing at a stabilized pressure, an RF power source is activated at an activation step 408 to strike the plasma to etch the wafers. The plasma is a carbon monoxide plasma, comprising carbon monoxide and any additives. At this point simultaneous on-going events occur within the chamber: 1) a plasma etch is in process relative to the wafers, 2) a volatile by-product is generated due to a chemical reaction between the gases flowing into the chamber and the material being etched, and 3) volatile by-products of the etch process are evacuated from the chamber as they are generated. These simultaneous events continue for a sufficient period of time to complete the desired etch of the transition metal or transition metal compound. When the desired etch is accomplished, the process goes to an end step 410.

It will be understood by those skilled in the art that some of the by-product may well be deposited on the wafers within the chamber as well as the chamber walls which may be potential sources of residue. The majority of the volatile by-product is however pumped out of the chamber.

Considering now the gas flow into the chamber in greater detail, a primary etchant of carbon monoxide gas, hereinafter simply called CO, is chosen for its specific reaction with transition metals and transition metal compounds. That is, a primary benefit of using CO as a primary etchant is that it reacts with most transition metals and transition metal compounds to form metal carbonyls that are volatile or that have relatively low boiling points. This is an important aspect of the present invention because the volatile by-product can be easily and quickly removed during etch which, in turn, results in significantly lower defect levels.

Sometimes gases, such as passivant gases that produce by-products that stick to the chamber walls or to the side walls of the wafer(s) being etched are deliberately added and are an integral part of the gas flow into the chamber. The addition of such passivant gases is done either to control the etch profile on the individual wafers and/or to maintain a particular chamber condition. Particular passivant gases that facilitate this process will be described hereinafter in greater detail.

While etching, it is necessary to ensure that the surface that is being etched stays free of residue while a passivating by-product sticks to the etched sidewalls. Ion assistance helps in ensuring that any passivating by-product does not stay on the surface being etched. Such ion assistance may be provided by added gases. This is important because if the passivating by-product stays on the surface being etched, it may cause the etch to stop or to be incomplete. In any event, by-products that stick to the sidewalls are removed in a subsequent conventional cleaning process that will not be described hereinafter in greater detail.

Considering the plasma etching process 400 in still greater detail, once the plasma etcher is stabilized and activated, the primary etchant, which is carbon monoxide (CO) plasma and any required additives, facilitate the plasma etch of the wafers disposed within the chamber. The term carbon monoxide based plasma will refer to a plasma which is largely carbon monoxide but which may include other additives. As the etching process is progressing, the CO reacts with the material to be etched (whether it be a transition metal or a transition metal compound, including oxides, nitrides and suicides) yielding a metal carbonyl by-product which is immediately evacuated from the chamber as quickly as it is formed. From the foregoing, it should be understood that this process allows the metal carbonyl by-product, which is a gaseous by-product, to be easily withdrawn from the etcher.

Additives that may be flowing with the CO can include either individually or in any combination such additives as reducing agents like H₂ and hydrofluorocarbons, passivants like N₂ and fluorocarbons, and additives that provide ion assistance, such as argon and BCl₃.

Although the volatile metal carbonyl by-product has been described as a gas, it will be understood by those skilled in the art that the metal carbonyl by-product may also be a liquid. There is no intention of limiting the preferred embodiment to a gaseous type of metal carbonyl as a liquid type of metal carbonyl is also contemplated. In either case however, the metal carbonyl by-product may be easily and conveniently removed from the plasma etcher by a pumping action during etch.

Referring now to FIG. 3, a specific example will be provided to illustrate how the plasma etch process 400 can be applied to specific types of applications. As a first example, a process for forming a nonvolatile memory cell will be described in greater detail.

The process for forming a nonvolatile memory cell begins by providing layers to be etched above a wafer surface. Referring to FIG. 3, the structure to be formed includes a bottom conductor 500, a barrier layer 502, a vertically oriented semiconductor junction diode 504, a compound stack 514, and a top conductor 512. The compound stack 514 includes titanium nitride layer 506, nickel oxide layer 508, and titanium nitride layer 510. The word stack is utilized in this specification to mean an operative layer of material which may or may not be associated with other layers of operative materials that may be disposed below or above, or below and above, the first mentioned material layer. The layers in such a stack may be conducting or insulating.

It will be understood that in a conventional process, the structure shown in FIG. 3 is one of a large array of such structures formed at the same time on a single wafer. Only one such structure is shown for simplicity.

At the time the etch according to an embodiment of the present invention is to be performed, bottom conductor 500, barrier layer 502, and junction diode 504 have already been formed by conventional deposition and pattern and etch processes. These structures are surrounding by dielectric fill (not shown) which has been planarized, forming a top planar surface.

The layers of the compound stack 514 (titanium nitride layer 506, nickel oxide layer 508, and titanium nitride layer 510) have been deposited, and are to be patterned and etched to form the structure shown in FIG. 3 (Top conductor 512 will be formed in later conventional processes which will not be described herein.) FIG. 3 shows the compound stack 514 in perfect alignment with the underlying diode 504. In reality there may be some misalignment.

Next a photolithographic step will be performed. A layer of photoresist (not shown) is spun on top of top titanium nitride layer 510. Using a photomask in a conventional process, some areas of the photoresist are exposed, while others are not. A developing process removes the photoresist that has been exposed, while leaving behind the photoresist that was not exposed. In this way a pattern is transferred from a photomask to the photoresist. The etch step of the present invention will transfer the pattern from the photoresist above the compound stack to the underlying layers of the compound stack. As will be appreciated by those skilled in the art, additional layers, such as a hard mask, may exist. For example, the pattern may be transferred from the photoresist to the hard mask, then from the hard mask to the compound stack.

The wafer including compound stack 514 is then loaded into a plasma etcher at the load step 404 to allow the plasma etch.

Once the plasma chamber has been loaded (step 404), stabilized (step 406) and activated (step 408), the activate or etch/evacuate process (step 408) begins. In this illustrative example, the etch/evacuate process is performed in two parts as will be explained hereinafter in greater detail.

In the present application example, the stack 514 (FIG. 3) of titanium nitride on bottom, nickel oxide in the middle, and titanium nitride on top needs to be patterned as a post/pillar on top of junction diode 504. U.S. patent application Ser. No.: 11/125,939, entitled “Rewritable Memory Cell Comprising a Diode and Resistance-Switching Material”, by S. Brad Herner and Christopher J. Petti, hereby incorporated by reference, describes a rewriteable memory cell like the structure of FIG. 3, comprising a vertically oriented polycrystalline semiconductor diode arranged in series with nickel oxide layer, wherein the nickel oxide layer can be switched between resistivity states. The nickel oxide layer is between barrier layers or electrode layers, for example, as in the structure of FIG. 3, of titanium nitride. The stack to be etched, then, includes, from the top, a titanium nitride layer (or other suitable electrode), a nickel oxide layer, and a second titanium nitride layer. This etch can be performed using embodiments of the present invention. For completeness, it should be understood that in some alternative embodiments, the TiN—NiO—TiN stack is deposited before the polycrystalline diode 504 has been etched, and all of these layers are etched in a single pattern and etch step.

Considering now the activate step 408 in still greater detail, in the activate step a carbon monoxide based chemistry is used to plasma etch the nickel oxide in the stack 310, and thus, produces a volatile by-product of nickel carbonyl. The foregoing chemical reaction is expressed by Equation 1:
NiO+5CO→Ni(CO)₄+CO₂ Equation (1)

More generally, this may be expressed in Equations 2 and 3 as follows:
TM+xCO→TM(CO)ₓ Equation (2)
where TM means transition metal.
TMOy+(x+y)CO→TM(CO)ₓ+yCO₂ Equation (3)

If argon is utilized as an additive to the CO, it will provide ion assistance during the plasma etch process. Similarly, if needed, other passivants such as N₂ may be added to the CO plasma to assist in etching and profile control. The top and bottom titanium nitride layers can be etched using conventional fluorine-based chemistry. These can be done as part of the NiO etching in separate sub-steps performed before and after the NiO etch.

If a reducing ambient is required, then other reactive gases such as CH₃F, CH₂F₂ or H₂ may be employed.

As an alternative to the oxide etcher, a metal or poly etcher may be used if CO is made available. In this case a Cl₂/BCl₃ based chemistry or a Cl₂/HBr chemistry is used to etch the titanium nitride.

The etch of the structure 514 occurs in three steps. First, an oxide etcher is used to provide a fluorine plasma to etch titanium nitride layer 508 within the stack 514, and then to provide the carbon monoxide plasma to etch nickel oxide layer 508 in the stack 514. Finally the etch chemistry is changed back to a fluorine-based chemistry to etch titanium nitride layer 506. The areas of the wafer surface that are not protected by photoresist are etched during this etch step, while the protected areas remain. In this way the structure shown in FIG. 3 is formed. As described earlier, the by-product resulting from the CO gas etch is immediately evacuated as fast as it is formed during the etch.

As the carbon monoxide plasma reacts with the nickel oxide, a volatile nickel carbonyl by-product is formed, which is evacuated as it is formed. From the foregoing, it will be understood that since the by-product is a gas, it can quickly and easily be exhausted from the plasma etcher leaving a cleanly etched end product. The process stops at an end step 410 when the etch is completed.

It should be understood that the fluorine etching steps only became necessary since the nickel oxide was sandwiched between a layer of top and bottom titanium nitride. In short, if TiN layers are present in the stack structure of 514, the corresponding fluorine etching steps are not necessary.

Considering the process of using a carbon monoxide plasma for etching a transition metal such as nickel oxide in greater detail, it should be understood by those skilled in the art that using carbon monoxide as an etchant is not limited to etching only nickel and nickel oxide as noted earlier. That is, the process can be applied equally well to other transition metals and other transition metal compounds, such as iron and oxides of iron, for example. In this regard, the same methodology can be utilized to etch other transition metals, their oxides or other associated compounds. In short, one of the key benefits of using carbon monoxide as an etchant is that it reacts with most transition metals to form metal carbonyls that are volatile or that have relatively low boiling points. This, in turn results in significantly lower defect levels. This is an important aspect of the present invention.

Another important aspect of the present invention is that carbon monoxide can also act as a reducing agent and hence transition metal oxides can also be etched in a carbon monoxide containing plasma. It should also be understood by those skilled in the art that other gases may be required and used in a plasma etcher. For example Ar/BCl₃ may provide energetic ion bombardment; hydrogenated fluorocarbons or H₂ may be useful in providing a reducing ambient, if needed.

In an example application of using carbon monoxide plasma as a primary etchant, a process has been described relative to a stack of titanium nitride, nickel oxide, titanium nitride. Other examples would include forming a vertically oriented semiconductor junction diode with a transition metal or transition metal oxide above or below the semiconductor junction diode and then plasma etching the structure above or below the semiconductor junction diode with carbon monoxide-based plasma.

As is described further in Herner et al., when a plurality of structures like those shown in FIG. 3 has been formed above a substrate (for example above a monocrystalline silicon wafer), a first memory level has been formed. Additional memory levels can be formed above the first one, forming a monolithic three dimensional memory array. Each nonvolatile memory cell resides in the monolithic three dimensional memory array.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, “Three dimensional structure memory.” The substrates may be thinned or removed from the memory levels before bonding, but as the memory levels are initially formed over separate substrates, such memories are not true monolithic three dimensional memory arrays.

A monolithic three dimensional memory array formed above a substrate comprises at least a first memory level formed at a first height above the substrate and a second memory level formed at a second height different from the first height. Three, four, eight, or indeed any number of memory levels can be formed above the substrate in such a multilevel array.

From the foregoing, it should be understood that the use of a sandwiched structure is for providing an example of the application of carbon monoxide plasma as a primary etchant only. In this regard, it is contemplated that the method of using carbon monoxide as an etchant can be applied to many other types of transition metals, their oxides and compounds of transition metal oxides.

While a particular embodiment of the present invention has been disclosed, it is to be understood that various different modifications are possible and are contemplated within the true spirit and scope of the appended claims. There is no intention, therefore, of limitations to the exact abstract or disclosure herein presented.

1. A plasma etching method, comprising:
causing carbon monoxide-based plasma to react with a transition metal to form a metal carbonyl gas while simultaneously plasma etching said transition metal.

2. The plasma etching method according to claim 1, wherein said transition metal is selected from a group of transition metals consisting of nickel, iron, cobalt, manganese, molybdenum, tungsten and ruthenium.

3. The plasma etching method according to claim 1 wherein the method further comprises exposing photoresist above the transition metal to transfer a pattern to the photoresist before the causing step.

4. The plasma etching method according to claim 3 wherein, during the causing step, the pattern is transferred from the photoresist to the transition metal.

5. A plasma etching method, comprising:
causing carbon monoxide-based plasma to react with a transition metal compound to form a carbonyl gas while simultaneously plasma etching said transition metal compound.

6. The plasma etching method according to claim 5, wherein said transition metal compound is selected from a group of transition metal compounds consisting of oxides, nitrides, and silicides.

7. The plasma etching method according to claim 5, wherein said transition metal compound is nickel oxide.

8. The plasma etching method according to claim 5 wherein the method further comprises exposing photoresist above the transition metal compound to transfer a pattern to the photoresist before the causing step.

9. The plasma etching method according to claim 8 wherein, during the causing step, the pattern is transferred to the transition metal compound.

10. A method of etching, comprising:
using carbon monoxide-based plasma to plasma etch a selected transition metal; and
forming a volatile metal carbonyl by-product.

11. The method according to claim 10, wherein said volatile metal carbonyl by-product is in the form of a gas.

12. The method according to claim 10, wherein said volatile metal carbonyl by-product is a liquid.

13. The method according to claim 10, wherein said carbon monoxide-based plasma acts as a reducing agent.

14. The method according to claim 10, the method further comprising exposing photoresist above the selected transition metal to transfer a pattern to the photoresist before the step of using carbon monoxide-based plasma to plasma etch the selected transition metal.

15. The method according to claim 14 wherein, during the step of using carbon monoxide-based plasma to plasma etch a selected transition metal, the pattern is transferred to the selected transition metal.

16. A method of etching, comprising:
using carbon monoxide-based plasma to plasma etch a selected transition metal compound; and
forming a volatile by-product of metal carbonyl.

17. The method according to claim 16, wherein said volatile by-product of metal carbonyl is a gas.

18. The method according to claim 16, wherein said volatile by-product of metal carbonyl is a liquid.

19. The method according to claim 16, wherein said carbon monoxide-based plasma acts as a reducing agent.

20. The method according to claim 16, the method further comprising exposing photoresist above the selected transition metal compound to transfer a pattern to the photoresist before the step of using carbon monoxide-based plasma to plasma etch the selected transition metal compound.

21. The method according to claim 20 wherein, during the step of using carbon monoxide-based plasma to plasma etch a selected transition metal compound, the pattern is transferred to the selected transition metal compound.

22. A method of etching, comprising:
exposing any one of the following:
a transition metal; or
a transition metal oxide; or
a transition metal compound;
to a primary etchant to plasma etch and form a metal carbonyl by-product.

23. The method of etching according to claim 22, wherein said primary etchant is carbon monoxide plasma.

24. The method of etching according to claim 23, wherein said metal carbonyl by-product is a gas.

25. The method of etching according to claim 23, wherein said metal carbonyl by-product is a liquid.

26. The method of etching according to claim 23, wherein said transition metal oxide is nickel oxide.

27. The method of etching according to claim 23, wherein other gas or gases are introduced with said carbon monoxide plasma.

28. The method of etching according to claim 27, wherein said other gas or gases are selected from a group of gases consisting of: reducing agents, passivants, and gases providing ion assistance.

29. The method of etching according to claim 26 wherein said nickel oxide is stacked with at least one other conducting material.

30. The method of etching according to claim 29, wherein said at least one other conducting material is titanium nitride.

31. The method of etching according to claim 26 wherein said nickel oxide is stacked with at least one other insulating material.

32. The method according to claim 26, further comprising:
using a passivant to assist the carbon monoxide gas plasma in etching said nickel oxide.

33. The method according to claim 32, wherein said passivant is N₂.

34. The method according to claim 22, wherein a reducing agent is required.

35. The method according to claim 34, wherein said reducing agent additive is selected from a group of additives consisting such as of: CH₂F₂, H₂, and CH₃F.

36. The method according to claim 26, wherein said nickel oxide is disposed about a layer of titanium nitride.

37. The method according to claim 36, wherein said titanium nitride is etched with Cl₂, BCl₃, HBr or other fluorocarbon gases as primary etchants.

38. The method according to claim 22 wherein a layer of photoresist above the transition metal, transition metal oxide, or transition metal compound is developed to transfer a pattern to the layer of photoresist.

39. The method according to claim 38 wherein the pattern is transferred to the transition metal, transition metal oxide, or transition metal compound during the exposing step.

40. A method of forming a nonvolatile memory cell, comprising:
forming a vertically oriented semiconductor junction diode;
forming a transition metal layer, or a transition metal oxide layer, or a transition metal compound layer about said diode; and
plasma etching said transition metal layer, transition metal oxide layer, or transition metal compound layer structure with carbon monoxide to cause gaseous metal carbonyl by-product to be formed as a by-product.

41. The method of claim 40 wherein the nonvolatile memory cell resides in a monolithic three dimensional memory array.
